(19) United States
(12) Patent Application Publication
(10) Pub. No.: US 2025/0238589 A1
(43) Pub. Date: Jul. 24, 2025

(54) INTEGRATED CIRCUIT DESIGN METHOD AND SYSTEM EMPLOYING PARASITIC DIODE ANALYSIS

(71) Applicant: GlobalFoundries U.S. Inc., Malta, NY (US)

(72) Inventors: Simona Milenova Dimitrova, Sofia (BG); Romain H.A. Feuillette, Williston, VT (US); Mariya Bozhidarova Stanoeva, Sofia (BG); Stephen Trevor Burgess, Sofia (BG)

(21) Appl. No.: 18/418,405

(22) Filed: Jan. 22, 2024

(51) Int. Cl. G06F 30/398

(52) U.S. Cl. CPC G06F 30/398

(57) ABSTRACT

Disclosed are embodiments of computer-aided design (CAD) methods and systems that employ one or more electronic design automation (EDA) tools to flag parasitic diodes within a layout or netlist (depending upon the embodiments). In one embodiment, information contained in process design kit (PDK) tables (e.g., a first table with layer-specific design rules for devices in a processing technology and a second table with descriptions of parasitic diodes in the processing technology) can be used to identify any parasitic diodes within a displayed portion of an IC design layout. Once identified, parasitic diodes can be flagged within the displayed portion of the layout to provide visual cues intended to draw a user's attention to the parasitic diodes during the design process to ensure that any unintended or unwanted parasitic diodes are either accounted for when predicting IC performance or removed from the design to avoid a negative impact on performance.

### BACKGROUND

The present disclosure relates to integrated circuits (ICs) and, more particularly, to embodiments of IC design methods and systems.

Factors considered in modern IC design include, but are not limited to, performance improvement, power consumption, and size scaling. Typically, iterative design processing is performed in order to generate an IC design layout optimized for performance, power, and area (PPA). However, if within the IC design layout there is overlap between layers having different type conductivities (i.e., having P-type and N-type conductivities), parasitic diodes are unintentionally created. These parasitic diodes can impact performance. Thus, if such parasitic diodes are not detected, flagged, and accounted for during iterative design processing (e.g., during repeated simulating and revising of the IC design layout), ICs manufactured according to a final IC design layout may not perform as expected such that yield is lower than expected.

### SUMMARY

Disclosed herein are embodiments of a computer-implemented integrated circuit design method and system employing parasitic diode analysis.

In some disclosed embodiments, the method can include displaying, by a processor (e.g., in response to user inputs via a graphic user interface (GUI) on a display monitor), a portion of an integrated circuit (IC) design layout. The method can further include accessing, by the processor from a storage medium, a first table and a second table related to a particular processing technology. The first table can include layer-specific design rules for devices in the particular processing technology. The second table can include descriptions of standard parasitic diodes processing technology. The method can further include using, by the processor, the first table and the second table to identify parasitic diodes present within the displayed portion of the layout. The method can further include flagging, by the processor, the identified parasitic diodes. This flagging can include inserting visual cues into the displayed portion of the layout to draw the user's attention to the identified parasitic diodes.

In other disclosed embodiments, the method can include receiving, by a processor (e.g., from a user via a GUI on a display monitor), selections indicating a section of a netlist and at least some parasitic diodes included as line items in the selected section. The method can further include displaying, by the processor (e.g., via the GUI), a portion of an IC design layout corresponding to the selected section of the netlist. The method can further include flagging, by the processor, the selected parasitic diodes within the displayed portion of the layout. This flagging can include inserting visual cues into the displayed portion of the layout to draw the user's attention to the selected parasitic diodes.

In still other disclosed embodiments, the method can include displaying, by a processor (e.g., in response to user inputs via a GUI on a display monitor), a portion of an IC design layout. The method can include receiving, by the processor (e.g., from the user via the GUI), a selection indicating an area of the displayed portion of the layout. The method can further include accessing, by the processor, a section of a netlist corresponding to the displayed portion of the layout. The method can further include flagging, by the processor, any parasitic diodes that are listed as line items within the section of the netlist and that are included in the selected area of the displayed portion of the layout. This flagging can include inserting visual cues into the section of the netlist to draw the user's attention to the parasitic diodes within the selected area.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating disclosed embodiments of a computer-aided design (CAD) system that can be employed to implement disclosed method embodiments;

FIG. 2 is a flow diagram illustrating a disclosed embodiment of a computer-implemented design method;

FIG. 3.1 is an example graphic user interface (GUI) screenshot generated during the method of FIG. 2;

FIGS. 3.2 and 3.3 are examples of tables employed during the method of FIG. 2;

FIGS. 3.4-3.7 are examples of GUI screenshots generated during the method of FIG. 2;

FIG. 4 is a flow diagram illustrating another disclosed embodiment of a computer-implemented design method;

FIGS. 5.1-5.5 are examples of GUI screenshots generated during the method of FIG. 4;

FIG. 6 is a flow diagram illustrating yet another disclosed embodiment of a computer-implemented design method;

FIGS. 7.1-7.4 are examples of GUI screenshots generated during the method of FIG. 6; and

FIG. 8 is a schematic diagram illustrative of an example hardware environment that can be employed to implement aspects of disclosed systems, methods and computer program products.

### DETAILED DESCRIPTION

As mentioned above, factors considered in modern IC design include, but are not limited to, performance improvement, power consumption, and size scaling. Typically, iterative design processing is performed in order to generate an IC design layout optimized for performance, power, and area (PPA). However, if within the IC design layout there is overlap between layers having different type conductivities (i.e., having P-type and N-type conductivities), parasitic diodes are unintentionally created. These parasitic diodes can impact performance. Thus, if such parasitic diodes are not detected, flagged, and accounted for during iterative design processing (e.g., during repeated simulating and revising of the IC design layout), ICs manufactured according to a final IC design layout may not perform as expected such that yield is lower than expected.

In view of the foregoing, disclosed herein are embodiments of computer-aided design (CAD) methods and systems that employ one or more electronic design automation (EDA) tools to flag parasitic diodes within a layout or netlist (depending upon the embodiments) displayed within a window of a graphic user interface (GUI). In a first embodiment, information contained in process design kit (PDK) tables (i.e., a first table with layer-specific design rules for devices in a processing technology and a second table with descriptions of parasitic diodes in the processing technology) can be used to identify any parasitic diodes located within a displayed portion of an IC design layout. Once identified, parasitic diodes can be flagged within the displayed portion of the IC design layout. This first embodiment is advantageous because it does not require the use of a netlist. Thus, it can be performed prior to execution of layout versus schematic and parasitic extraction tools so the turn-around time (TAT) for parasitic diode analysis is relatively fast. In a second embodiment, a section of an extracted netlist and at least some parasitic diodes listed therein can be selected by a user. Then, a portion of an IC design layout corresponding to the selected section of the netlist can be displayed with the selected parasitic diodes flagged. In a third embodiment, a portion of an IC design layout can be displayed. Next, a user can select an area of the displayed portion of the IC design layout to be analyzed. Then, a section of a netlist corresponding to the displayed portion of the IC design layout can be accessed and any line items within the section of the netlist and associated with parasitic diodes located within the selected area can be flagged. Since the second and third embodiments require a netlist, they can only be performed following execution of layout versus schematic and parasitic extraction tools. Thus, they have a slower turn-around time (TAT) for parasitic diode analysis than the first embodiment. However, these embodiments can be used with relatively large or complicated IC designs to help user visualize all parasitic diodes that are located outside of the compact models. Optionally, additional embodiments can include combinations of the various flagging techniques discussed above. Also, optionally, in each of the disclosed embodiments, the user can, via the GUI, filter out certain parasitic diodes from those previously selected or flagged. For example, one or more different types of parasitic diodes could be filtered out. Also, optionally, in each of the disclosed embodiments, a parasitic diode report, which defines the parasitic diodes selected and/or flagged, using the above-described techniques can be generated and output to a user (e.g., via the GUI or otherwise output to a user, such as by printing, email, etc.). In any case, in the above-described embodiments, flagging of parasitic diodes in the layout or netlist is done to provide visual cues intended to draw a user's attention to parasitic diodes during the design process to ensure that any unintended or unwanted parasitic diodes are either accounted for when predicting IC performance or removed from the design to avoid a negative impact on performance.

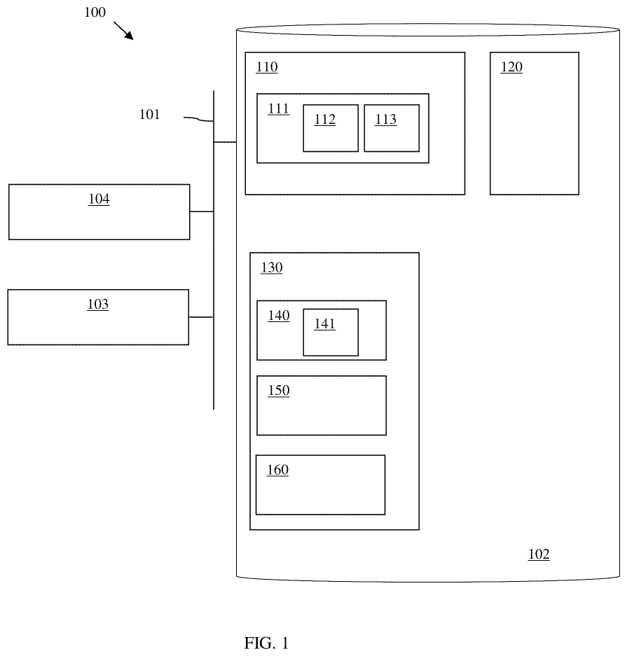

More particularly, FIG. 1 is a schematic diagram illustrating disclosed embodiments of a computer-aided design (CAD) system 100. CAD system 100 can include multiple system components. These system components can include, but are not limited to, one or more processors 103, one or more display monitors 104, and one or more computer readable storage mediums 102. The system components can be interconnected over a system bus 101 (as illustrated) and/or over a wired or wireless network. For purposes of illustration, CAD system 100 is described below and illustrated in FIG. 1 as having a single processor, a single display monitor, and a single storage medium. However, it should be understood that FIG. 1 is not intended to be limiting. Alternatively, CAD system 100 could incorporate multiple processors for performing one or more of the different processes in a design flow, multiple display monitors, and/or multiple storage mediums, which are accessible by the processor(s) and which store the required data, software tools, etc. for performing the different processes in the design flow. Furthermore, all system components can be co-located. Alternatively, the various system components can be incorporated into a distributed system whose components are located on different networked computers.

Storage medium 102 can store electronic design automation (EDA) tool(s) 130 (e.g., specialized software program(s)). Each EDA tool 130 includes program instructions that are executable by processor 103 to cause processor 103 to perform process steps in a computer-aided integrated circuit (IC) design flow. Such EDA tools 130 can include, but are not limited to, a design layout tool 140, a parasitic extraction (PEX) tool 160, and a layout versus schematic (LVS) tool 150.

A design layout tool 140 refers to a tool configured to assist a user with generating a layout for an IC design (also referred to herein as an IC design layout). A user, in the context of computer-aided IC design, typically refers to an IC designer. Such a layout includes a representation of the IC design. The representation includes planar geometric shapes which correspond to different layers of the IC design. The layout or portions thereof can be developed and edited by a user via the tool's graphic user interface (GUI) 141 displayed on a display monitor 104. Generally, design layout tools are well known in the art and, thus, the details thereof have been omitted from the specification except for any additional design layout tool features disclosed herein and discussed in greater detail below.

A PEX tool 160 refers to a tool configured to assist a user with analyzing the layout for an IC to identify and calculate parasitics (e.g., parasitic resistances, capacitances, diodes, inductances, etc.). Generally, PEX tools are well known in the art and, thus, the details thereof have been omitted from the specification except for any additional PEX tool features disclosed herein and discussed in greater detail below.

An LVS tool 150 refers to a tool configured to assist a user with analyzing the layout to ensure design rules have been met (e.g., to perform a design rules check). Specifically, an LVS tool 150 can be configured to analyze an IC design layout (e.g., acquired from design layout tool 140) and the identified parasitics (e.g., acquired from PEX tool 160) to generate a netlist, which is representative of the IC design. Those skilled in the art will recognize that a netlist includes a list of electronic components in the IC design (including parasitic diodes that are outside the compact model) and the nodes that the electronic components are connected to. Generally, LVS tools are well known in the art and, thus, the details thereof have been omitted from the specification except for any additional PEX tool features disclosed herein and discussed in greater detail below.

Storage medium 102 can further store design information, which is accessible and usable by one or more EDA tools 130 during performance of the IC design flow. Design information can be for a specific technology node (also referred to herein as a specific processing technology). Optionally, the design information can be in the form of a process design kit (PDK) 110. A PDK 110 is a set of electronic files including both data and script files. A PDK is typically developed by a semiconductor foundry for its customers in order to facilitate design of ICs at a specific technology node supported by the foundry. The electronic files within the PDK are accessible by one or more EDA tools executed on a CAD system at different stages in the design flow. Exemplary PDK electronic files include, but are not limited to, simulation models, symbols and technology files 111, a cell library, and design rule decks. Technology files 111 can include, among other files, various tables and lists applicable to the specific technology node. These tables and lists can include, for example, a table (referred to herein as a first table 112) with layer-specific design rules for devices available at the specific technology node. That is, first table 112 can list the various devices available that the specific technology node and, for each device, the applicable design rules on a layer by layer basis. These tables and lists can include, for example, another table (referred to herein as a second table 113) with descriptions of all parasitic diodes that can occur within ICs at the specific technology node. PDKs are well known in the art and, thus, the details thereof have been omitted from the specification except for any additional PDK features disclosed herein and discussed in greater detail below.

Storage medium 102 can further store previously generated design files 120 including, but not limited to, generated design layouts and netlists for ICs or portions thereof.

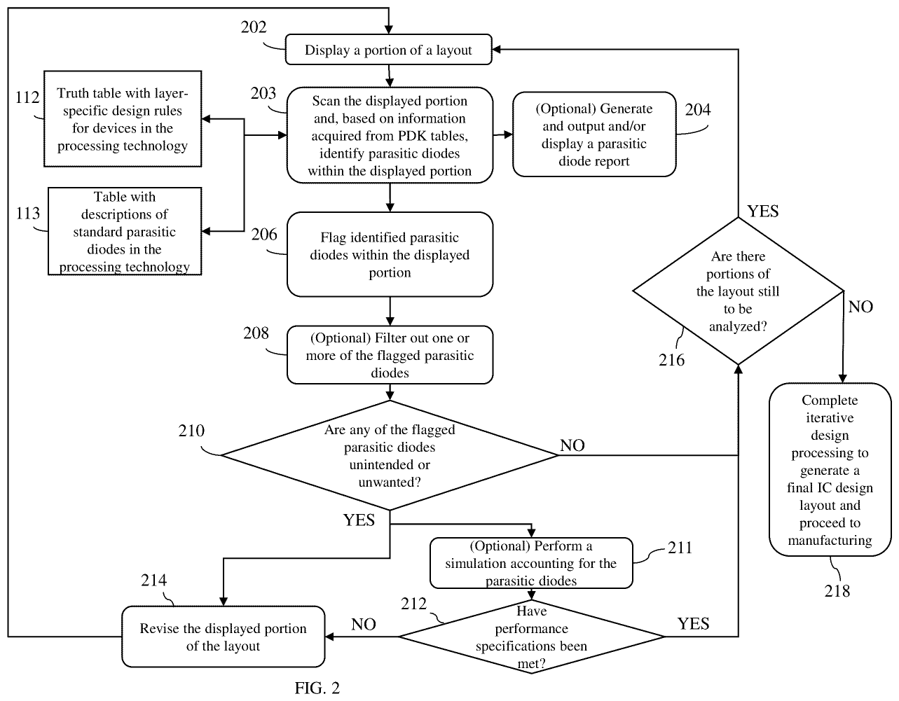

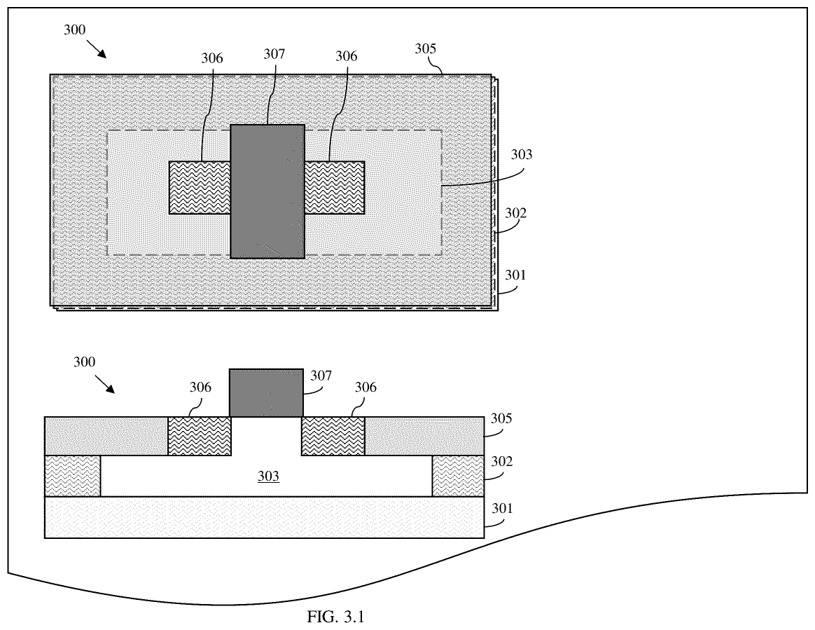

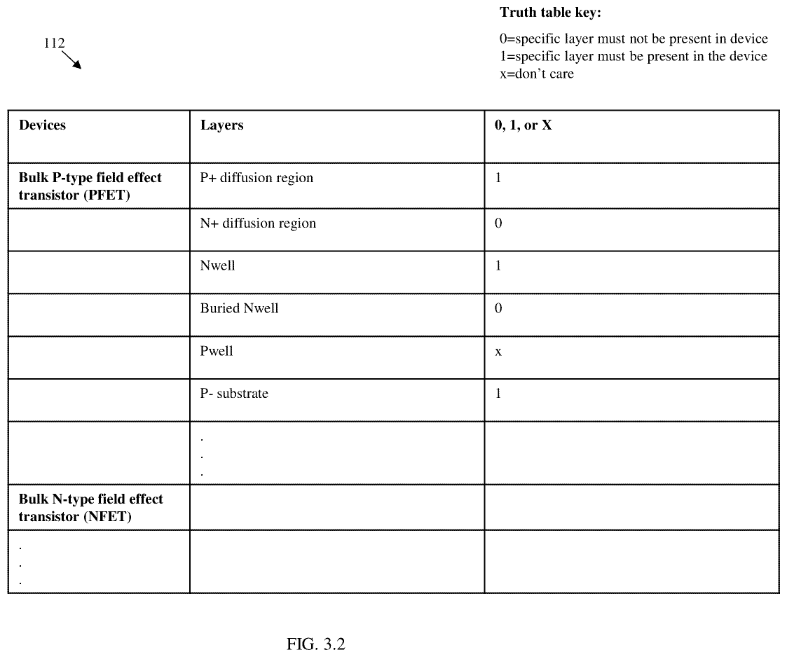

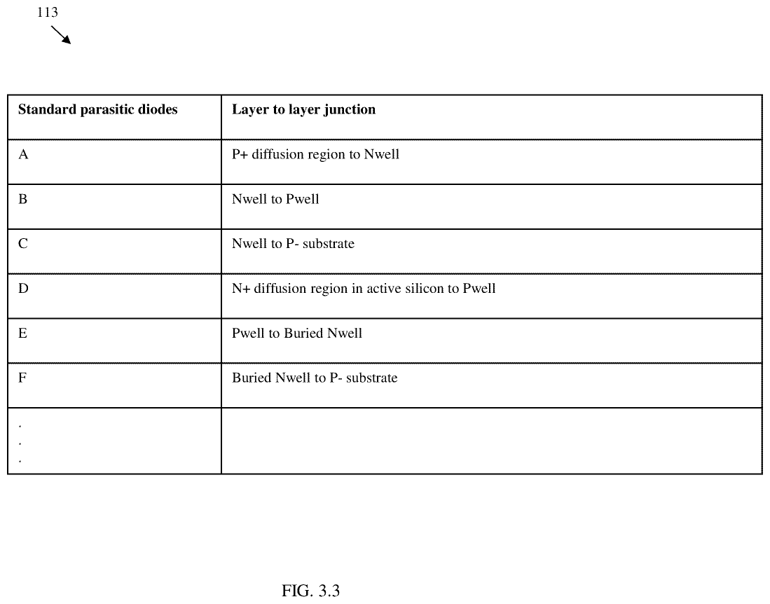

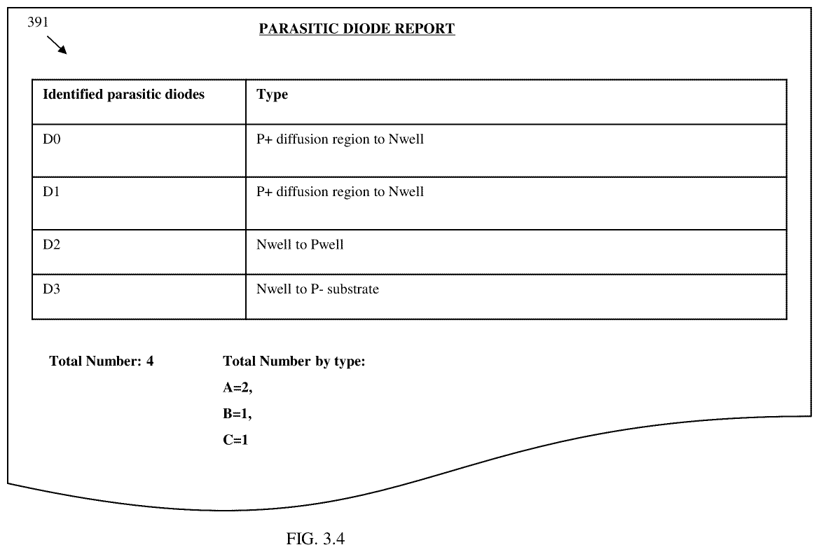

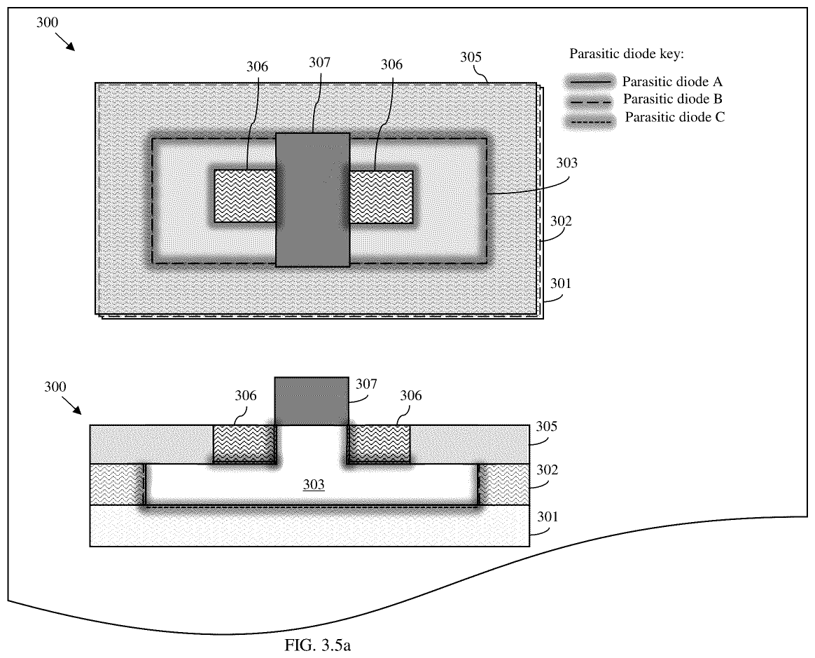

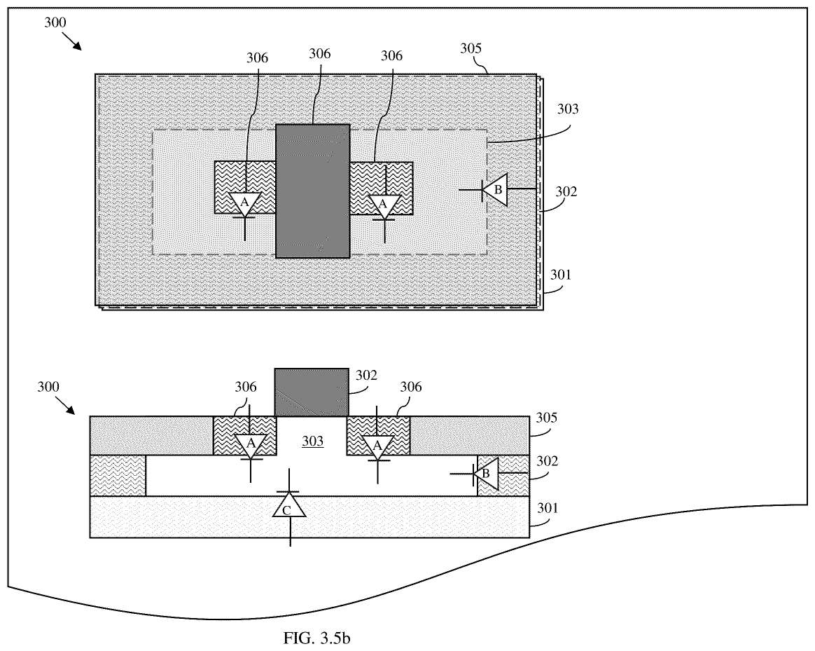

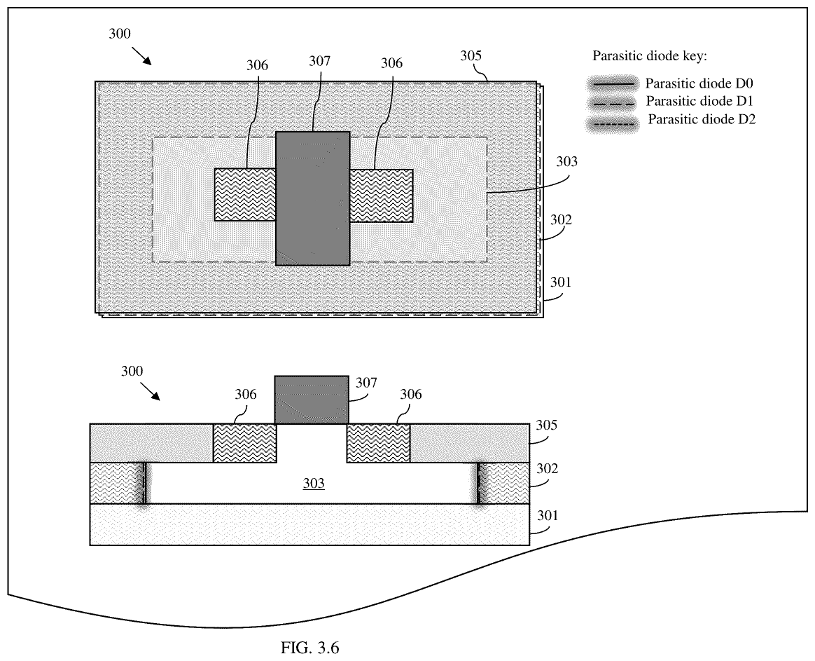

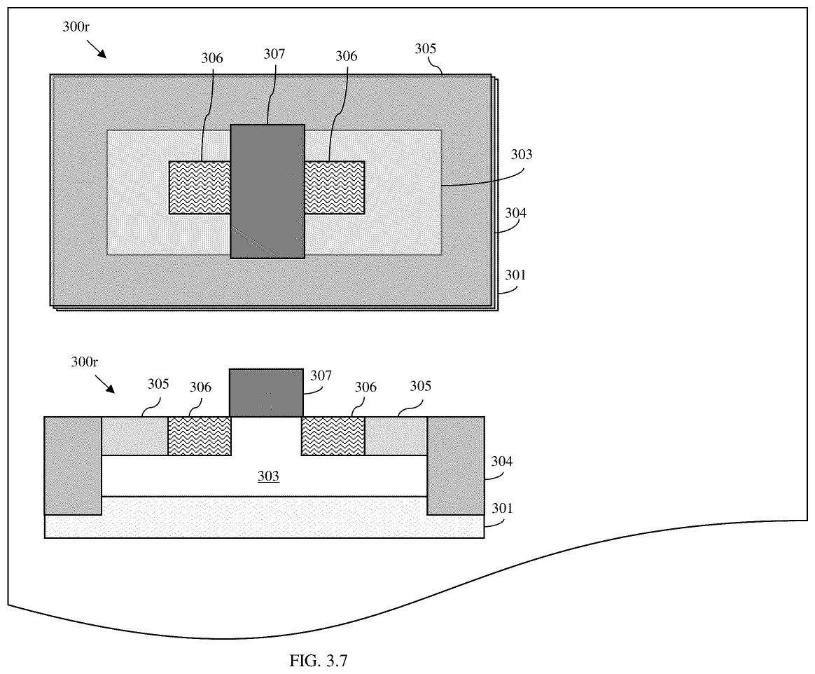

FIG. 2 is a flow diagram illustrating an embodiment of a method that can be implemented using the above-described CAD system 100 of FIG. 1. The method can include displaying, on a display monitor 104 of CAD system 100, at least a portion 300 of an IC design layout that was previously stored in storage medium 102 (see process 202 and FIG. 3.1). Display of the portion 300 of the IC design layout can be performed, for example, by processor 103 in response to user inputs received via GUI 141 of design layout tool 140.

FIG. 3.1 is an example screenshot showing such a portion 300 of an IC design layout displayed via GUI 141 of design layout tool 140 on display monitor 104. This portion 300 of the IC design layout includes two different views of the same portion 300: one is a top down or layout view and the other is a cross-section view along the length of the device. For purposes of illustration, portion 300 of the IC design layout shown in FIG. 3.1 is a bulk P-type field effect transistor (PFET). However, it should be understood that FIG. 3.1 is not intended to be limiting. Alternatively, the displayed portion 300 of the IC design layout could be a FET with a different type conductivity (e.g., a bulk NFET), a different type of transistor (e.g., a semiconductor-on-insulator FET, a bipolar junction transistor (BJT), a junction field effect transistor (JFET), etc.), a different type of device (e.g., a capacitor, a silicon-controlled rectifier (SCR), a diode, etc.), a group of one or more of such devices, a cell (standard or parameterized), a relatively large section of the IC design layout, or the entire IC design. In any case, in the example screenshot shown in FIG. 3.1, the displayed portion 300 of the IC design layout includes a semiconductor substrate 301 with P-type conductivity at a relatively low conductivity level (e.g., a P-semiconductor substrate). Trench isolation regions 305 are within semiconductor substrate 301 at the top surface, defining an active device region for the PFET. The PFET includes, within semiconductor substrate 301, an N-type well region (Nwell) 303, which is laterally surrounded by a P-type well region (Pwell) 302. The PFET further includes, within the Nwell 303 in the active device region, source/drain regions 306 and a channel region positioned laterally between the source/drain regions 306. The source/drain regions 306 can have P-type conductivity at a relatively high conductivity level (e.g., P+source/drain regions). The PFET further include a gate structure 307 on the top surface of semiconductor substrate 301 over the channel region.

The method can further include performing, by processor 103, a parasitic diode analysis including accessing, by processor 103 from technology files 111 of PDK 110 stored in storage medium 102, a set of tables including: a first table 112 (also referred to herein as a truth table) with layer-specific design rules for devices in the processing technology at issue and a second table 113 with descriptions of standard parasitic diodes found within ICs formed in the processing technology at issue. FIG. 3.2 is an example of a first table 112. As illustrated, this first table 112 includes a list of devices available in the processing technology at issue (e.g., bulk PFET, bulk NFET, etc.). For each device, this first table 112 lists different processing layers (e.g., P+ diffusion regions, N+ diffusion regions, Nwell, buried Nwell, etc.) and, for each layer, indicates whether that specific layer must not be present (0), must be present (1), or does not matter (X). Thus, for example, for a PFET, the P+ diffusion region, Nwell, and P− substrate must be present. The N+ diffusion region and buried Nwell must not. FIG. 3.3 is an example of a second table 113. As illustrated, this second table 113 lists standard parasitic diodes by identifier. For purposes of illustration, identifiers A, B, C, D, etc. are used. However, any other suitable identifier could alternatively be used. In any case, the second table 113 provides a description of each of the standard parasitic diodes (e.g., by layer-to-layer junction, such as P+ diffusion region to Nwell, Nwell to Pwell, etc.).

The parasitic diode analysis can further include scanning, by the processor 103, the displayed portion 300 of the IC design layout and further using the information provided in these two tables 112-113 to identify all parasitic diodes therein (see process 203).

Optionally, the parasitic diode analysis can include generating, by the processor 103, a parasitic diode report 391 (see process 204 and FIG. 3.4). Parasitic diode report 391 can, for example, include a list of all identified parasitic diodes (e.g., D0-D3) and can indicate the type of parasitic diode (e.g., P+ diffusion region to Nwell, Nwell to Pwell, etc.). Parasitic diode report 391 can also, optionally, indicate the total number of parasitic diodes identified within the displayed portion 300 of the IC design layout and the total number of each type of parasitic diode. Such a parasitic diode report 391 can be stored in storage medium 102, output to a user such as by means of a printer, email, digital notification, etc., and/or displayed on display monitor 104 via GUI 141.

The parasitic diode analysis can further include flagging, by the processor 103, identified parasitic diodes on the displayed portion 300 of the IC design layout (see process 206). All of the identified parasitic diodes in the displayed portion 300 could be flagged at process 206. Alternatively, the parasitic diode report 391 generated at process 204 above could be presented to the user in a GUI window and the identified parasitic diodes listed therein can be user selectable. In this case, only user-selected ones of the identified parasitic diodes from the parasitic diode report 391 could be flagged in the displayed portion.

Flagging of the identified parasitic diodes can include inserting visual cues into the displayed portion 300 of the IC design layout to draw attention to the identified parasitic diodes. For example, as illustrated in FIG. 3.5a, such flagging can include adjusting glow formatting of all lines within the displayed portion 300 that indicate the PN junctions of the identified parasitic diodes. Alternatively, any other suitable formatting adjustment could be employed to flag the identified parasitic diodes including, but not limited to, adjusting shadow formatting, adjusting color formatting, adjusting line weight, and adjusting line dash pattern of those lines that indicate the PN junctions. Alternatively, as illustrated in FIG. 3.5b, such flagging can include placing parasitic diode indicators over the lines indicating the PN junctions. Furthermore, it should be understood that different flagging techniques could be employed for different parasitic diodes types. For example, all parasitic diodes could be flagged by adjusting glow formatting and different types of parasitic diodes could be flagged with different colors of glow formatting. Alternatively, all parasitic diodes could be flagged with a parasitic diode indicator and different types of parasitic diodes could be labeled (e.g., A, B, C, etc.).

Optionally, the parasitic diode analysis can further in filtering out, by the processor 103 (e.g., in response to user inputs via a GUI or specific design criteria), one or more of the flags associated with one or more of the identified parasitic diodes (see process 208). That is, for one or more of the identified parasitic diodes the visual cue can be removed. For example, see FIG. 3.6 where flags (i.e., visual cues) for all parasitic diodes except the Nwell to Pwell parasitic diodes have been removed from the displayed portion 300 of the IC design layout.

The above-described parasitic diode analysis is advantageous because it does not require the use of a netlist. Thus, it can be performed prior to execution of layout versus schematic and parasitic extraction tools so the turn-around time (TAT) for parasitic diode analysis is relatively fast.

Once the parasitic diode analysis is complete, a determination can be made (e.g., manually by a user or automatically by the processor) as to whether or not any of the flagged parasitic diodes in the displayed portion 300 of the IC design layout (e.g., as indicated in any of FIGS. 3.5a-3.6) are any unintended or unwanted parasitic diodes (see process 210). If so, the displayed portion 300 of the IC design layout can be revised (e.g., to remove the unintended or unwanted parasitic diodes) (see process 214). For example, as illustrated in FIG. 3.7, in response to user inputs received through the GUI 141 of the design layout tool 140, a revised portion 300r of the IC design layout can be generated with deep trench isolation (DTI) regions 304 replacing the Pwells that laterally surround the Nwell 303, thereby completely removing all Pwell-to-Nwell parasitic diodes. Alternatively, before removing any parasitic diodes, a simulation could be performed (e.g., using a conventional simulation tool) accounting for the parasitic diodes (see process 211). Following the simulation, a determination can be made as to whether or not performance specifications would be met even with the inclusion of the unintended or unwanted parasitic diodes (see process 212). If not, the displayed portion 300 of the IC design layout can be revised, as discussed above (see process 214). If none of the flagged parasitic diodes are unintended or unwanted or if the results of a simulation indicate that performance specifications would still be met even if the unintended or unwanted parasitic diodes remain in the IC design layout, a determination can be made as to whether or not there are any other portions of the IC design layout still to be analyzed (see process 216). If so, the method could be repeated for different portions of the IC design layout. If not, then iterative design processing can be completed in order to generate a final IC design layout, which is released to manufacturing, and ICs could be manufactured according to the final IC design layout (see process 218).

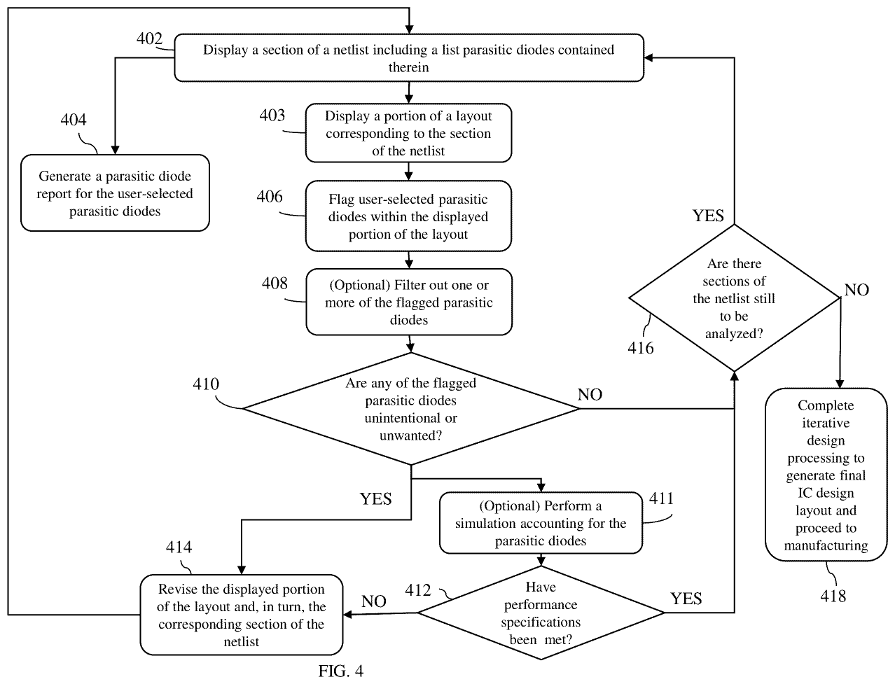

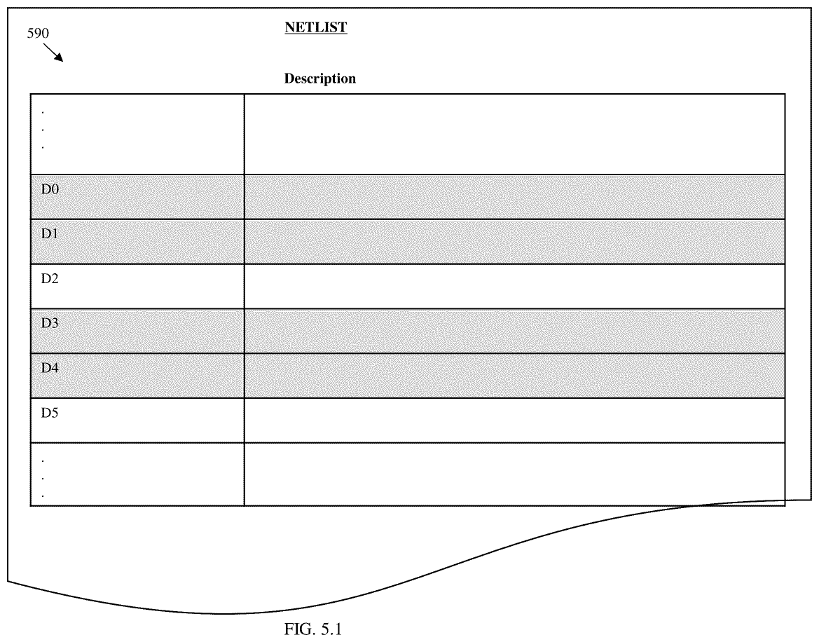

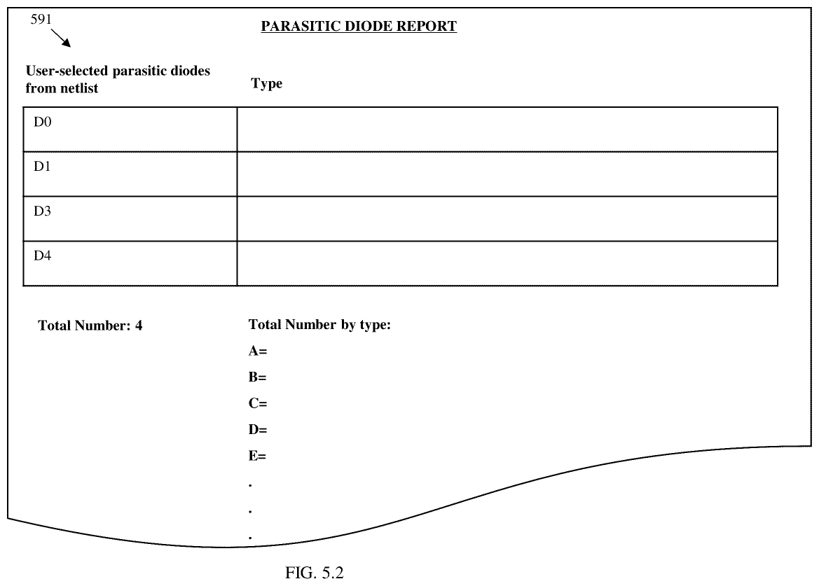

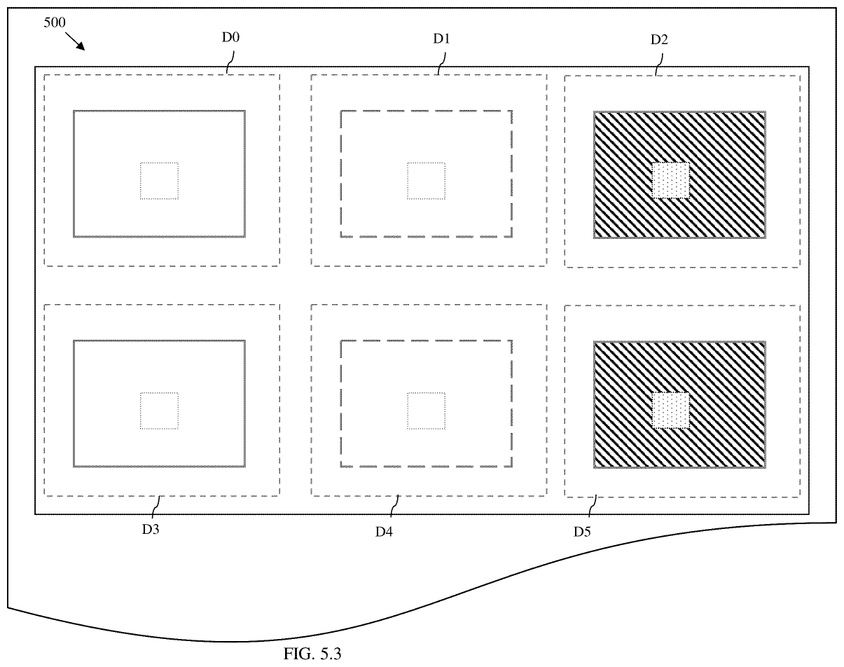

FIG. 4 is a flow diagram illustrating another embodiment of a method that can be implemented using the above-described CAD system 100 of FIG. 1. The method can include displaying, by a processor 103 on a display monitor 104 of the CAD system 100, a user-selected section 590 of a netlist for an IC design (see process 402 and FIG. 5.1). As mentioned above, a netlist is generated following execution of the LVS tool and includes a list of electronic components in an IC design (including parasitics, such as parasitic diodes that are outside the compact model) and the nodes that the electronic components are connected to. For purposes of illustration, FIG. 5.1 shows line items for parasitic diodes D0-D5. However, those skilled in the art will recognize that, within a netlist, such parasitic diodes will typically be listed by specific names that indicate the type of parasitic diode and will be accompanied by some form of description. Such details have been omitted from the specification in order to avoid clutter in the figures and allow the reader to focus on the salient aspects of the disclosed embodiments.

The method can further include performing, by processor 103, a parasitic diode analysis. Optionally, the parasitic diode analysis can include receiving, by processor 103 from a user, inputs indicating selection of one or more of the parasitic diodes D0-D5 listed within the displayed section 590 of the netlist. Selection of specific parasitic diodes can be made, for example, via any currently known or later developed GUI technique. For purposes of illustration, the selected parasitic diodes are shown in FIG. 5.1 as being highlighted in gray (i.e., D0, D1, D3 and D4 have been selected).

Optionally, the parasitic diode analysis can include generating, by the processor 103, a parasitic diode report 591 (see process 404 and FIG. 5.2). Parasitic diode report 591 can, for example, include a list of the selected parasitic diodes (e.g., D0, D1, D3, and D4) and their respective types. Parasitic diode report 591 can also, optionally, indicate the total number of selected parasitic diodes as well as the total number of each type. Such a parasitic diode report 591 can be stored in storage medium 102, output to a user such as by means of a printer, email, digital notification, etc., and/or displayed via a GUI on display monitor 104.

The parasitic diode analysis can also include displaying at least a portion 500 of an IC design layout that corresponds to section 590 of the netlist (see process 403 and FIG. 5.3). Display of portion 500 of the IC design layout can be performed, for example, by processor 103 on display monitor 104 of CAD system 100 in response to user inputs received via GUI 141 of design layout tool 140. The displayed portion 500 can include, for example, a relatively large portion of an IC design layout including multiple devices and/or multiple cells (standard or parameterized).

The parasitic diode analysis can further include flagging, by the processor 103, the selected parasitic diodes (e.g., D0-D1 and D3-D4) within the displayed portion 500 of the IC design layout (see process 406). Flagging of the identified parasitic diodes can include inserting visual cues into the displayed portion 500 of the IC design layout to draw attention to the selected parasitic diodes. For example, as illustrated in FIG. 5.4, such flagging can include adjusting glow formatting of all lines within the displayed portion 500 that indicate the PN junctions of the selected parasitic diodes. Alternatively, any other suitable formatting adjustment could be employed to flag the identified parasitic diodes including, but not limited to, adjusting shadow formatting, adjusting color formatting, adjusting line weight, and adjusting line dash pattern of those lines that indicate the PN junctions. Alternatively, such flagging could include placing parasitic diode indicators over the lines indicating the PN junctions. Furthermore, it should be understood that different flagging techniques could be employed for different parasitic diodes types. For example, all parasitic diodes could be flagged by adjusting glow formatting and different types of parasitic diodes could be flagged with different colors of glow formatting. Alternatively, all parasitic diodes could be flagged with a parasitic diode indicator and different types of parasitic diodes could be labeled. Optionally, the method can further include filtering out, by the processor 103 (e.g., in response to user inputs or specific design criteria), one or more of the flags associated with one or more of the selected parasitic diodes (see process 408). That is, the visual cue associated with one or more of the selected parasitic diodes can be removed. For example, see FIG. 5.5 where flags (i.e., visual cues) for parasitic diodes D0 and D3 have been removed from the displayed portion 500 of the IC design layout.

Subsequently, a determination can be made (e.g., manually by a user or automatically by the processor) as to whether or not the flagged parasitic diodes in the displayed portion 500 of the IC design layout (e.g., as indicated in FIG. 5.4 or 5.5) are unintended or unwanted parasitic diodes (see process 410). If so, portion 500 of the IC design layout can be revised (e.g., to remove the unintended or unwanted parasitic diodes) and, in turn, the section of the netlist can also be revised (see process 414). Alternatively, before removing any parasitic diodes, a simulation can be performed (e.g., using a conventional simulation tool) accounting for the parasitic diodes (see process 411). Following the simulation, a determination can be made as to whether or not performance specifications will still be met even with the inclusion of the unintended or unwanted parasitic diode (see process 412). If not, the layout and netlist can be revised, as discussed above (see process 414). If none of the flagged parasitic diodes are unintended or unwanted or if the results of a simulation indicate that performance specifications would still be met even if unintended or unwanted parasitic diodes remain in the IC design layout, a determination can be made as to whether or not there are any other sections of the netlist still to be analyzed (see process 416). If not, then iterative design processing can be completed in order to generate a final IC design layout, which is released to manufacturing, and ICs could be manufactured according to the final IC design layout (see process 418).

In the embodiment described above and illustrated in the flow diagram of FIG. 4, the described process steps are not intended to be limiting. For example, at process 404, the parasitic diode report 591 could be presented to the user via a GUI and could include a list of all parasitic diodes contained within the user-selected section 590 of the netlist with the listed parasitic diodes being user-selectable. Parasitic diodes selected by the user from the parasitic diode report can subsequently be flagged at process 406. Alternatively, for example, once a portion of the IC design layout corresponding to the user-selected section 590 of the netlist is displayed at process 403, the user could use the GUI to select an area within the displayed portion of the IC design layout and only parasitic diodes located within that selected area could be flagged at process 406.

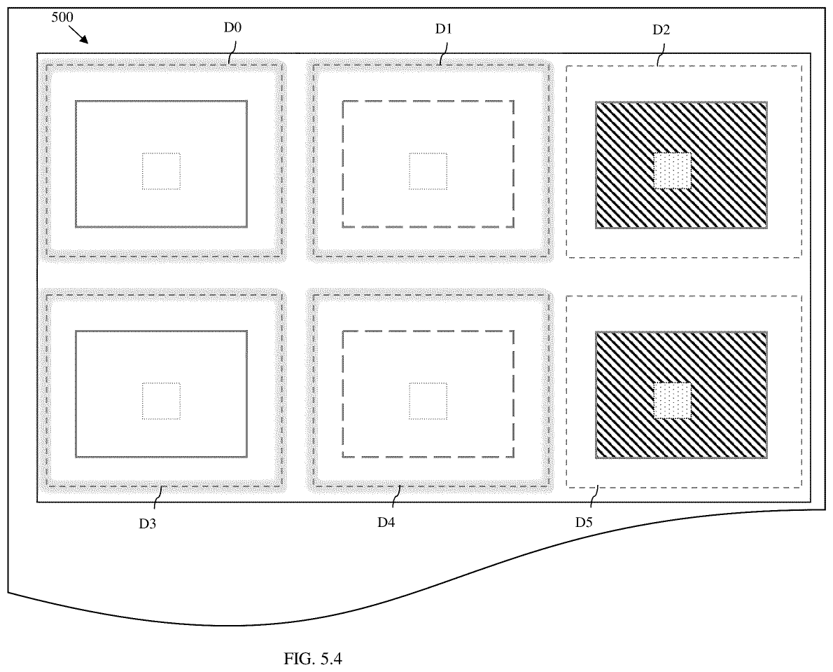

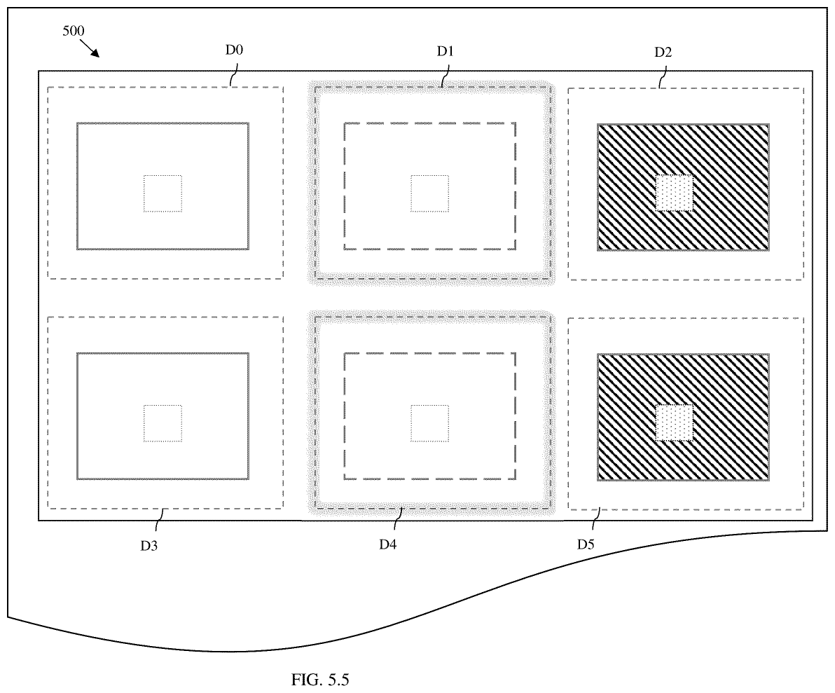

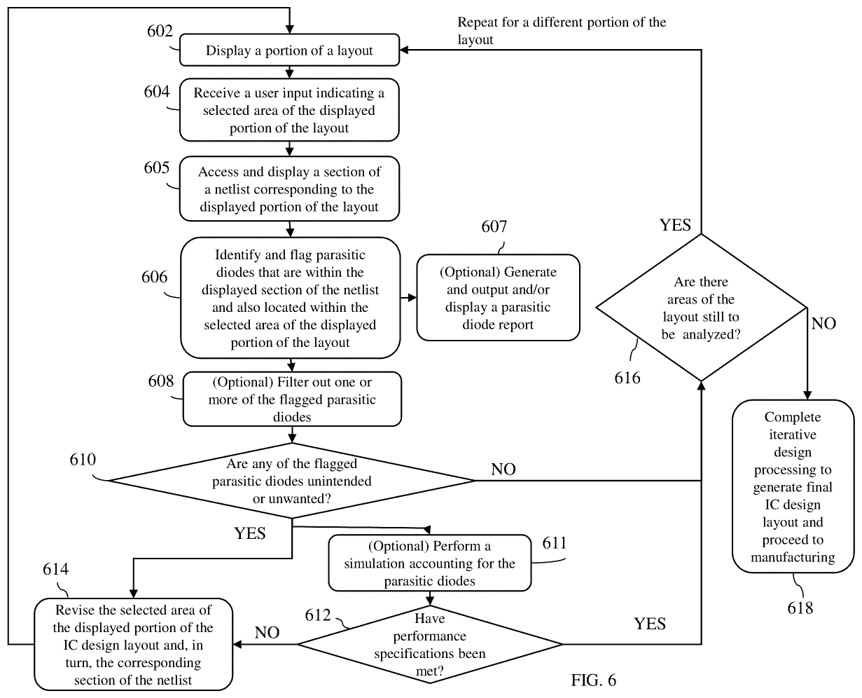

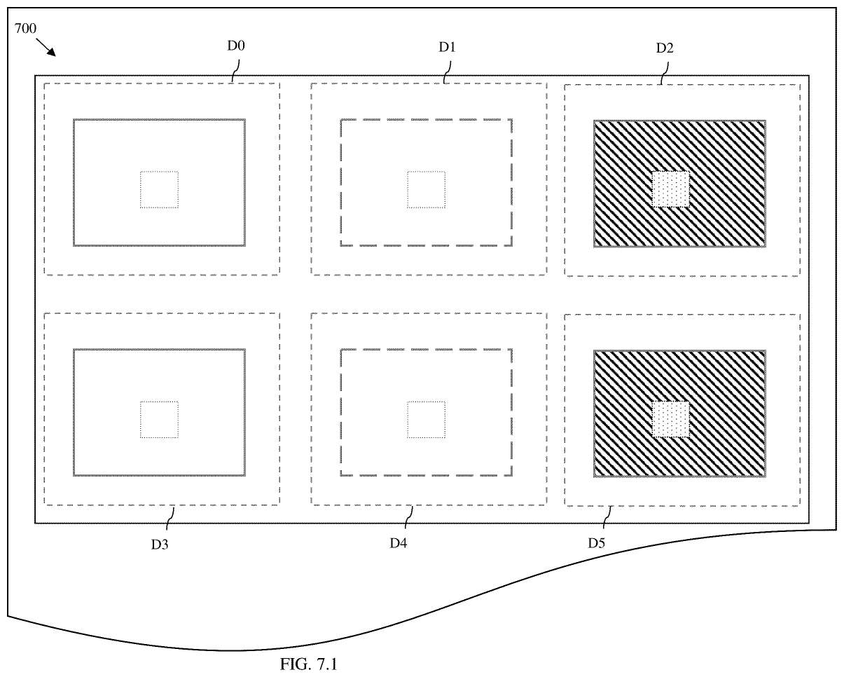

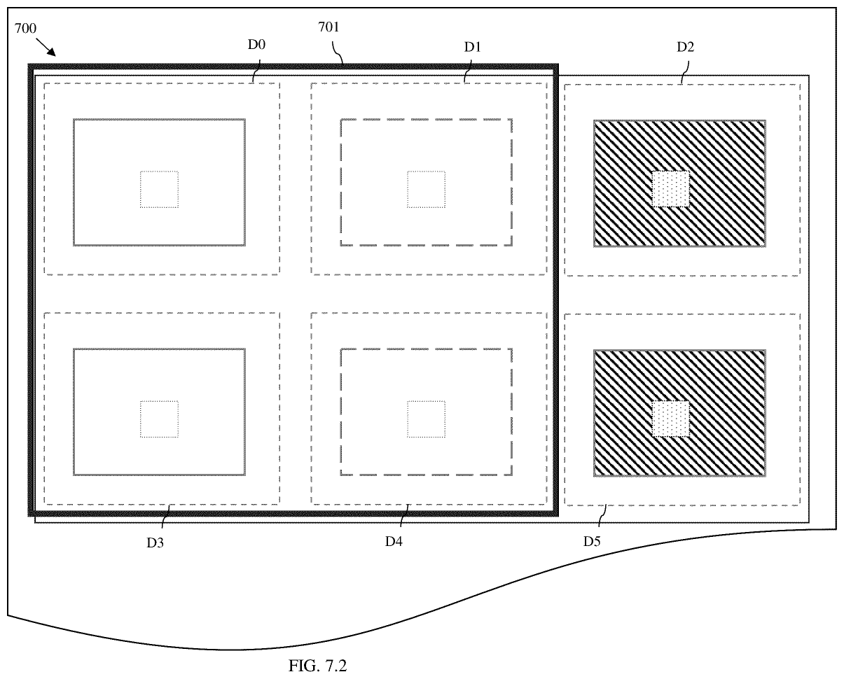

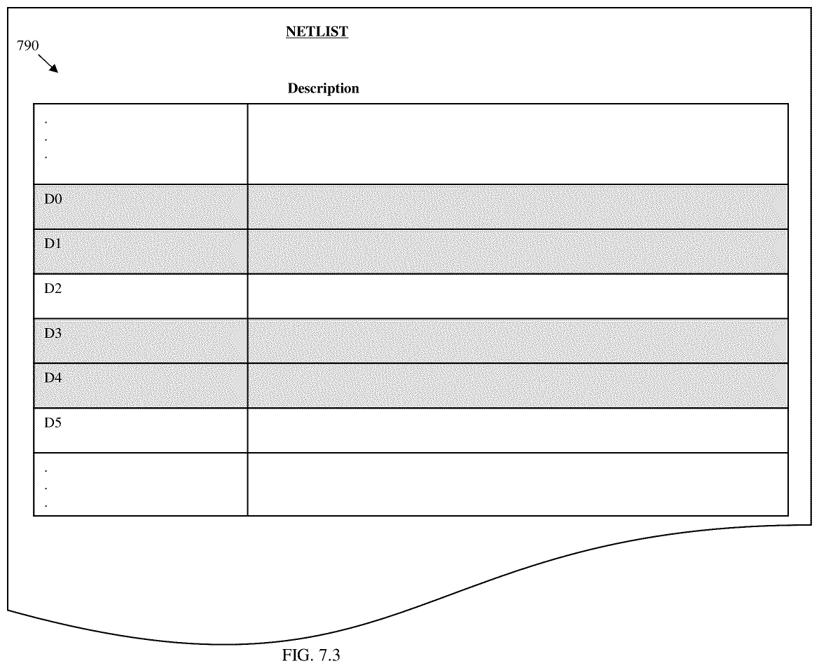

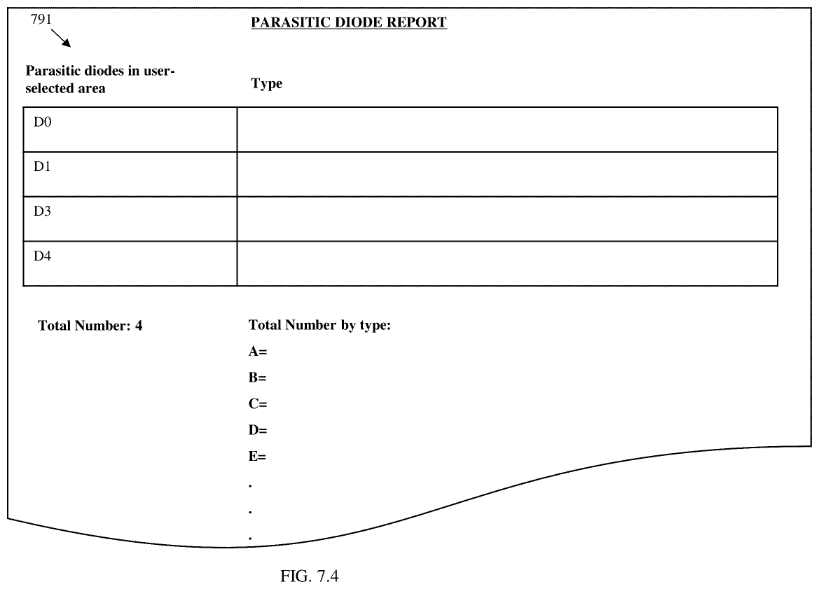

FIG. 6 is a flow diagram illustrating yet another embodiment of a method that can be implemented using the above-described CAD system 100 of FIG. 1. The method can include displaying, on a display monitor 104 of CAD system 100, at least a portion 700 of an IC design layout that was previously stored in storage medium 102 (see process 602 and FIG. 7.1). Display of the portion 700 of the IC design layout can be performed, for example, by processor 103 in response to user inputs received via GUI 141 of design layout tool 140. The method can further include receiving, by processor 103 from a user (e.g., via GUI 141), an input indicating a selection of a specific area 701 (also referred to herein as the selected area) of the displayed portion 700 of the IC design layout (see process 604 and FIG. 7.2). Selection of the specific area 701 can be made, for example, via any known GUI technique (e.g., by scrolling over the selected area while holding down the left-side button on a mouse, etc.). For purposes of illustration, a dark border defines selected area 701 in FIG. 7.2. Alternatively, any other visual indicator could be employed to define the selected area 701 (e.g., highlighting the entire area in a given color, etc.).

The method can further include performing, by processor 103, a parasitic diode analysis including accessing, by processor 103 from storage medium 102, a section 790 of a netlist corresponding to the previously displayed portion 700 of the IC design layout (see process 605 and FIG. 7.3). Section 790 of the netlist can further be displayed by processor 103 on display monitor 104 via a GUI of, for example, the LVS tool. As mentioned above, a netlist is generated following execution of the LVS tool and includes a list of electronic components in an IC design (including parasitics, such as parasitic diodes that are outside the compact model) and the nodes that the electronic components are connected to. For purposes of illustration, FIG. 7.3 shows line items for parasitic diodes D0-D5. However, those skilled in the art will recognize that, within a netlist, such parasitic diodes will typically be listed by specific names that indicate the type of parasitic diode and will be accompanied by some form of description. Such details have been omitted from the specification in order to avoid clutter in the figures and allow the reader to focus on the salient aspects of the disclosed embodiments.

The parasitic diode analysis can further include determining, by processor 103, which line items in the section 790 of the netlist correspond to parasitic diodes that are located within the selected area 701 of the previously displayed portion 700 of the IC design layout (see process 606 and FIG. 7.3). For example, as illustrated, in FIG. 7.2 only parasitic diodes D0, D1, D3 and D4 are included within the selected area 701.

The parasitic diode analysis can further include flagging, by processor 103 in the displayed section 790 of the netlist, all those line items corresponding to parasitic diodes that were located within the selected area 701 (see process 606 and FIG. 7.3). Flagging of the specific line items can be achieved using any currently known or later developed GUI technique. For purposes of illustration, D0, D1, D3 and D4 are illustrated as being highlighted in gray. Alternatively, any other flagging technique could be used. For example, the text color associated with these line items could be different (e.g., red), or asterisks could be placed next to the line items, etc. Optionally, the parasitic diode analysis can further in filtering out (i.e., removing), by the processor 103 (e.g., in response to user inputs or specific design criteria), one or more of the flags (i.e., the visual cues) associated with one or more of the parasitic diodes in the section 790 of the netlist (see process 608).

Optionally, the parasitic diode analysis can also include generating, by the processor 103, a parasitic diode report 791 (see process 607 and FIG. 7.4). Parasitic diode report 791 can, for example, include a list of only those parasitic diodes located within the selected area 701 (e.g., D0, D1, D3, and D4) and their respective types. Parasitic diode report 791 can also, optionally, indicate the total number of parasitic diodes within the selected area 701 as well as the total number of each type. Such a parasitic diode report 791 can be stored in storage medium 102, output to a user such as by means of a printer, email, digital notification, etc., and/or displayed via a GUI on display monitor 104.

Optionally, at process 606, instead of flagging all line items corresponding to parasitic diodes that were located within the selected area as described above, the parasitic diode report 791 generated at process 607 above could be presented to the user in a GUI window and the parasitic diodes listed therein could be user selectable. In this case, only user-selected ones of the parasitic diodes from the parasitic diode report 791 would be flagged. Subsequently, a determination can be made (e.g., manually by a user or automatically by the processor) as to whether or not any of the flagged parasitic diodes in the displayed section 791 of the netlist (e.g., as indicated in FIG. 7.3) are unintended or unwanted parasitic diodes (see process 610). If so, the portion 700 of the IC design layout can be revised (e.g., to remove the unintended or unwanted parasitic diodes) and, in turn, the section of the netlist can also be revised (see process 614). Alternatively, before removing any parasitic diodes, a simulation can be performed (e.g., using a conventional simulation tool) accounting for the parasitic diodes (see process 611). Following the simulation, a determination can be made as to whether or not performance specifications will still be met even with the inclusion of the unintended or unwanted parasitic diode (see process 612). If not, the layout and netlist can be revised, as discussed above (see process 614). If none of the flagged parasitic diodes are unintended or unwanted parasitic diodes or if the results of a simulation indicate that performance specifications would still be met even if unintended or unwanted parasitic diodes remain in the IC design layout, a determination can be made as to whether or not there are any other areas of the IC design layout to be analyzed (see process 616). If not, then iterative design processing can be completed in order to generate a final IC design layout, which is released to manufacturing, and ICs could be manufactured according to the final IC design layout (see process 618).

The methods as described above can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Embodiments disclosed herein may be a system, a method, and/or a computer program product. The computer program product may include a computer readable storage medium (or media) having computer readable program instructions thereon for causing a processor to carry out aspects of the disclosed embodiments.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the disclosed embodiments may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the disclosed embodiments.

Aspects of the disclosed embodiments are described herein with reference to flowchart illustrations and/or block diagrams of methods, apparatus (systems), and computer program products according to disclosed embodiments. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various disclosed embodiments. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

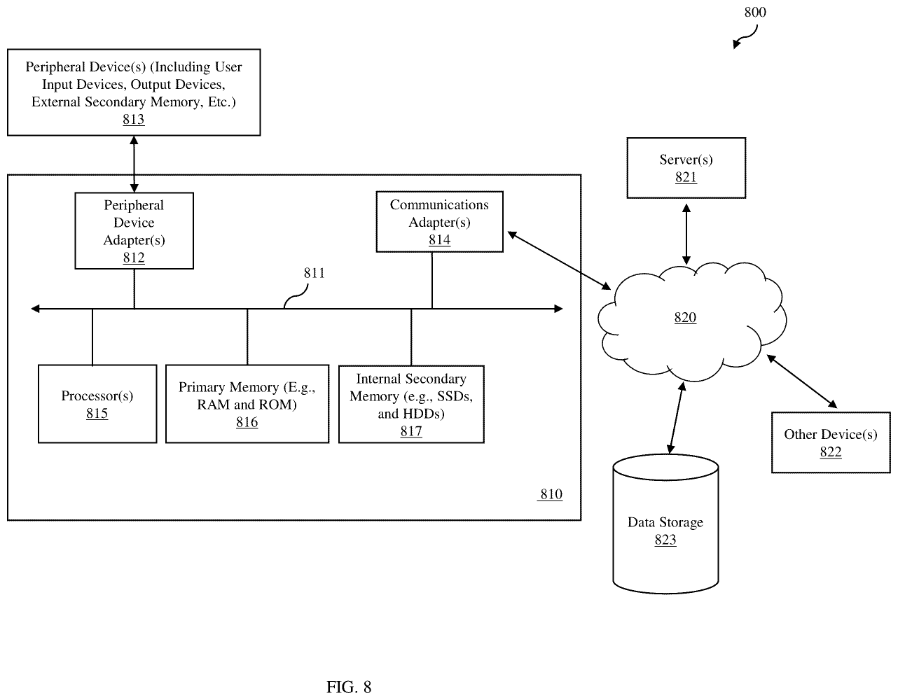

An illustrative hardware environment 800 for implementing aspects of the disclosed systems, methods and computer program products is depicted in FIG. 8. Generally, the hardware environment can include at least one computing device 810 (also referred to herein as a computer). The computer 810 can be, for example, a desktop, laptop, tablet, mobile computing device, etc. The computer 810 can include at least one bus 811. The bus 811 can be connected to various other components of the computer 810 and can be configured to facilitate communication between those components.

The computer 810 can include various adapters. The adapters can include one or more peripheral device adapters 812, which are configured to facilitate communications between one or more peripheral devices 813, respectively, and the bus 811. The peripheral devices 813 can include user input devices configured to receive user inputs. User input devices can include, but are not limited to, a keyboard, a mouse, a microphone, a touchpad, a touchscreen, a stylus, bio-sensor, a scanner, or any other type of user input device. The peripheral devices 813 can also include additional input devices, such as external secondary memory devices (as discussed in greater detail below). The peripheral devices 813 can also include output devices. The output devices can include, but are not limited to, a printer, a monitor, a speaker, or any other type of computer output device. The adapters can include one or more communications adapters 814 (also referred to herein as a computer network adapters), which are configured to facilitate communications between the computer 810 and one or more communications networks 820 (e.g., a wide area network (WAN), a local area network (LAN), the internet, a cellular network, a Wi-Fi network, etc.). Such communications network(s) 820 can, in turn, facilitate communications between the computer 810 and other system components on the network: remote server(s) 821, other device(s) 822 (e.g., computers, laptops, tablets, mobile phones, etc.), remote data storage 823, etc.

The computer 810 can further include at least one processor 815 (also referred to herein as a central processing units (CPU)). Optionally, each CPU 815 can include a CPU cache. Each CPU 815 can be configured to read and execute program instructions.

The computer 810 can further include memory and, particularly, computer-readable storage mediums. The memory can include primary memory 816 and secondary memory. The primary memory 816 can include, but is not limited to, random access memory (RAM) (e.g., volatile memory employed during execution of program operations) and read only memory (ROM) (e.g., non-volatile memory employed during start-up). The RAM can include, but is not limited to, dynamic random access memory (DRAM), static random access memory (SRAM), or any other suitable type of RAM. The ROM can include, but is not limited to, erasable programmable read only memory (EPROM), flash memory, electronically erasable programmable read only memory (EEPROM), programmable read only memory (PROM), or any other suitable type of ROM. The secondary memory can be non-volatile. The secondary memory can include internal secondary memory 817, such as internal solid state drive(s) (SSD(s)) and/or internal hard disk drive(s) (HDD(s), installed within the computer 810 and connected to the bus 811. The secondary memory can also include external secondary memory connected to or otherwise in communication with the computer 810 (e.g., peripheral devices). The external secondary memory can include, for example, external/portable SSD(s), external/portable HDD(s), flash drive(s), thumb drives, compact disc(s) (CD(s)), digital video disc(s) (DVD(s)), network-attached storage (NAS), storage area network (SAN), or any other suitable non-transitory computer-readable storage media connected to or otherwise in communication with the computer 810. The different functions of primary and secondary memory are well known in the art and, thus, the details thereof have been omitted from this specification in order to allow the reader to focus on the salient aspects of the disclosed embodiments.

In some embodiments, program instructions for performing the disclosed method or a portion thereof, as described above, can be embodied in (e.g., stored in) secondary memory accessible by the computer 810. When the program instructions are to be executed (e.g., in response to user inputs to the computer 810), required information (e.g., the program instructions and other data) can be loaded into the primary memory (e.g., stored in RAM). The CPU 815 can read the program instructions and other data from the RAM and can execute the program instructions. In other embodiments, a client-server model can be employed. In this case, the computer 810 can be a client and a remote server 821 in communication with the computer 810 over a communications network 820 can provide, to the client, a service including execution of program instructions for performing the disclosed method or a portion thereof, as described above, in response to user inputs the computer 810.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
displaying, by a processor, a portion of a layout;
accessing, by the processor, a first table with layer-specific design rules for devices in a processing technology and a second table with descriptions of parasitic diodes in the processing technology, wherein the first table and the second table are accessed from a storage medium;
using, by the processor, the first table and the second table to identify parasitic diodes within the displayed portion of the layout; and
flagging, by the processor, the identified parasitic diodes, wherein the flagging includes inserting visual cues into the displayed portion of the layout to draw attention to the identified parasitic diodes.

2. The method of claim 1, wherein the flagging of the identified parasitic diodes includes adjusting any of glow formatting, shadow formatting, color formatting, line weight, and line dash pattern of lines illustrating PN junctions within the displayed portion of the layout.

3. The method of claim 1, wherein the flagging of the identified parasitic diodes includes placing parasitic diode indicators over lines illustrating PN junctions within the displayed portion of the layout.

4. The method of claim 1, wherein the flagging of the identified parasitic diodes includes employing different flagging techniques for different parasitic diode types.

5. The method of claim 1, further comprising: filtering out, by the processor, at least one visual cue associated with at least one of the identified parasitic diodes flagged within the displayed portion of the layout.

6. The method of claim 1, further comprising generating, by the processor, a parasitic diode report indicating at least one of: different parasitic diode types within the displayed portion of the layout, numbers of the different parasitic diode types within the displayed portion of the layout, and a total number of the parasitic diodes within the displayed portion of the layout.

7. The method of claim 1, further comprising revising, by the processor, the displayed portion of the layout, wherein the revising includes removing at least one unintended parasitic diode.

8. A method comprising:
receiving, by a processor, a selection indicating a section of a netlist;
displaying, by the processor, a portion of a layout corresponding to the selected section of the netlist; and
flagging, by the processor, selected parasitic diodes within the displayed portion of the layout, wherein the flagging includes inserting visual cues into the displayed portion of the layout to draw attention to the selected parasitic diodes.

9. The method of claim 8, wherein the flagging of the selected parasitic diodes includes adjusting any of glow formatting, shadow formatting, color formatting, line weight, and line dash pattern of lines illustrating PN junctions within the displayed portion of the layout.

10. The method of claim 8, wherein the flagging of the selected parasitic diodes includes placing parasitic diode indicators over lines illustrating PN junctions within the displayed portion of the layout.

11. The method of claim 8, wherein the flagging of the selected parasitic diodes includes employing different flagging techniques for different parasitic diode types.

12. The method of claim 8, further comprising: filtering out, by the processor, at least one visual cue associated with at least one of the selected parasitic diodes flagged within the displayed portion of the layout.

13. The method of claim 8, further comprising generating, by the processor, a parasitic diode report indicating at least one of: different parasitic diode types within the displayed portion of the layout, numbers of the different parasitic diode types within the displayed portion of the layout, and a total number of the parasitic diodes within the displayed portion of the layout.

14. The method of claim 8, further comprising revising, by the processor, the displayed portion of the layout, wherein the revising includes removing at least one unintended parasitic diode.

15. A method comprising:
displaying, by a processor, a portion of a layout;
accessing, by the processor, a section of a netlist corresponding to a selected area of the displayed portion of the layout; and
flagging, by the processor, parasitic diodes that are listed as line items within the section of the netlist and that are included in the selected area of the displayed portion of the layout, wherein the flagging includes inserting visual cues into the section of the netlist to draw attention to the parasitic diodes within the selected area.

16. The method of claim 15, wherein the flagging of the parasitic diodes includes adjusting any of color formatting, highlight formatting, and bold formatting of the line items in the section of the netlist associated with the parasitic diodes within the selected area.

17. The method of claim 15, wherein the flagging of the parasitic diodes includes placing parasitic diode indicators adjacent to the line items in the section of the netlist associated with the parasitic diodes within the selected area.

18. The method of claim 15, wherein the flagging of the parasitic diodes includes employing different flagging techniques for different parasitic diode types.

19. The method of claim 15, further comprising: filtering out, by the processor, at least one visual cue associated with at least one of the parasitic diodes flagged within the section of the netlist.

20. The method of claim 15, further comprising: generating, by the processor, a parasitic diode report indicating at least one of: different parasitic diode types within the selected area of the displayed portion of the layout, numbers of the different parasitic diode types within selected area of the displayed portion of the layout, and a total number of the parasitic diodes within the selected area of the displayed portion of the layout.
